(19) United States
(12) Patent Application Publication
(10) Pub. No.: US 2008/0099887 A1
(43) Pub. Date: May 1, 2008

(54) MULTI-GROUND SHIELDING SEMICONDUCTOR PACKAGE, METHOD OF FABRICATING THE PACKAGE, AND METHOD OF PREVENTING NOISE USING MULTI-GROUND SHIELDING

(75) Inventors: Eun-Seok SONG, Seoul (KR); Hee-Seok LEE, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggid-do (KR)

(21) Appl. No.: 11/564,760

(22) Filed: Nov. 29, 2006

(30) Foreign Application Priority Data
Oct. 30, 2006 (KR) 2006-0105550

(51) Int. Cl. H01L 39/00

(52) U.S. Cl. 257/663

(57) ABSTRACT

Provided are a multi-ground shielding semiconductor package including analog and digital circuit blocks and capable of preventing a coupling problem between the analog and digital circuit blocks caused by high frequency noise. A method of fabricating the multi-ground shielding semiconductor package, and a method of preventing noise in the multi-ground shielding semiconductor package are also provided. The multi-ground shielding semiconductor package includes at least one semiconductor chip; and a circuit board on which the semiconductor chip is mounted and on which a plurality of circuit blocks are formed, wherein a conductive ground shielding is formed between the circuit blocks and separately from grounds of the circuit blocks to prevent noise between the circuit blocks.

### CROSS-REFERENCE TO RELATED PATENT APPLICATION

This application claims the benefit of Korean Patent Application No. 10-2006-0105550, filed on Oct. 30, 2006, in the Korean Intellectual Property Office, the disclosure of which is incorporated herein by reference in its entirety.

### BACKGROUND

1. Technical Field

The invention relates to a semiconductor device and a method of fabricating the same, and more particularly, to a semiconductor package including analog and digital circuit blocks, a method of fabricating the semiconductor package, and a method of preventing noise in the semiconductor package.

2. Description of the Related Art

Aided by the high integration of semiconductor devices, semiconductor packages in which analog and digital circuit blocks are integrated have become popular in recent times. For example, a plurality of circuit blocks are formed in a semiconductor package such as a package including analog/digital mixed signal chips, a system in package (SIP) including side-by-side mounted chips, a multi-stacked package (MSP) including stacked chips, and the like. In particular, analog and digital circuit blocks are formed together in these semiconductor packages.

In view of a power distribution network (PDN), it is important to properly design a power and a ground of a digital or analog block in a semiconductor chip. Also, in a circuit board of a package such as a mixed signal chip package, an SIP, an MSP, or the like, it is more important to isolate a power and a ground in a digital circuit block from a power and a ground in an analog circuit block.

In the case of an SIP, a logic chip, a memory chip, or other types of chips are packaged together. This structure packages together an analog circuit block to which analog signals including a radio frequency (RF) signal are transmitted and a digital circuit block to which digital signals are transmitted. In other words, the analog and digital circuit blocks coexist on a circuit board, and noise caused by an analog signal of the analog circuit block is coupled to a power and a ground of the digital circuit block and propagates along the power and ground. Thus, the propagated noise adversely affects the digital circuit block.

Accordingly, a method of isolating a ground of an analog circuit block from a ground of a digital circuit block on a circuit board to prevent such noise has been suggested. Even if the grounds of the analog and digital circuit blocks are isolated from each other though, high frequency noise of an analog signal may be propagated in the form of an electromagnetic wave.

Thus, the high frequency noise causes coupling between powers and grounds of the analog circuit blocks and those of the digital circuit blocks, and appears as noise in the digital circuit block.

FIG. 1 is a cross-sectional view of a conventional semiconductor package including a plurality of semiconductor chips. Referring to FIG. 1, the conventional semiconductor package includes a circuit board 19 and analog and digital semiconductor chips 13 and 14 mounted on the circuit board 19. The analog semiconductor chip 13 is used for an analog circuit, and the digital semiconductor chip 14 is used for a digital circuit. A signal coupling problem occurs even in the conventional semiconductor package in which the analog and digital chips 13 and 14 are isolated from each other. To solve the signal coupling problem, ground patterns, i.e., analog and digital ground patterns 20 and 21, are formed underneath the circuit board 19. Here, the analog and digital ground patterns 20 and 21 are respectively connected to the analog and digital semiconductor chips 13 and 14 through wires 16 and lead terminals 17.

A metal pattern 15 is formed on a semiconductor substrate 12 on which the analog and digital semiconductor chips 13 and 14 have been formed. The metal pattern 15 may be formed to prevent noise generated by an external source. Also, the semiconductor substrate 12 including the analog and digital semiconductor chips 13 and 14 is shielded by an insulator 18 such as an epoxy mold compound on the circuit board 19.

However, although the grounds of the analog and digital chips are isolated from each other, signal coupling between the analog and digital circuit blocks on a circuit board still occurs.

In other words, the digital chip is affected by high frequency noise. Such a coupling problem caused by high frequency noise may occur not only between circuit blocks or between semiconductor chips but also between pins or between wires, at which analog and digital signals coexist.

### SUMMARY

In one embodiment, a device comprises a circuit board; a plurality of conductive structures on the circuit board, wherein the plurality of conductive structures are connected to at least one ground; and a conductive ground shielding between the plurality of conductive structures, wherein the conductive ground shielding is connected to a ground different from the at least one ground.

### BRIEF DESCRIPTION OF THE DRAWINGS

The above and other features and advantages of the invention will become more apparent by describing in detail exemplary embodiments thereof with reference to the attached drawings in which:

FIG. 1 is a cross-sectional view of a conventional semiconductor package including a plurality of semiconductor chips;

FIG. 2 is a plan view of a semiconductor package in which a ground shielding is formed between analog and digital circuit blocks, according to an embodiment of the invention;

FIG. 3 is a detailed plan view of portion A of FIG. 2;

FIG. 4 is a plan view of a semiconductor package in which a ground shielding is formed between analog and digital circuit blocks, according to another embodiment of the invention;

FIG. 5 is a plan view of a semiconductor package in which a ground shielding is formed between analog and digital circuit blocks, according to yet another embodiment of the invention;

FIG. 6 is a plan view of a semiconductor package in which a ground shielding is formed in a noise source, according to another embodiment of the invention;

FIGS. 7A and 7B are a plan view and a cross-sectional view of a wafer level package (WLP) including a ground shielding according to another embodiment of the invention;

FIGS. 8A and 8B are views illustrating a conventional semiconductor package and a semiconductor package of the invention each including a ground shielding; and

FIG. 9 is a flowchart of a method of fabricating a semiconductor package including a ground shielding, according to an embodiment of the invention.

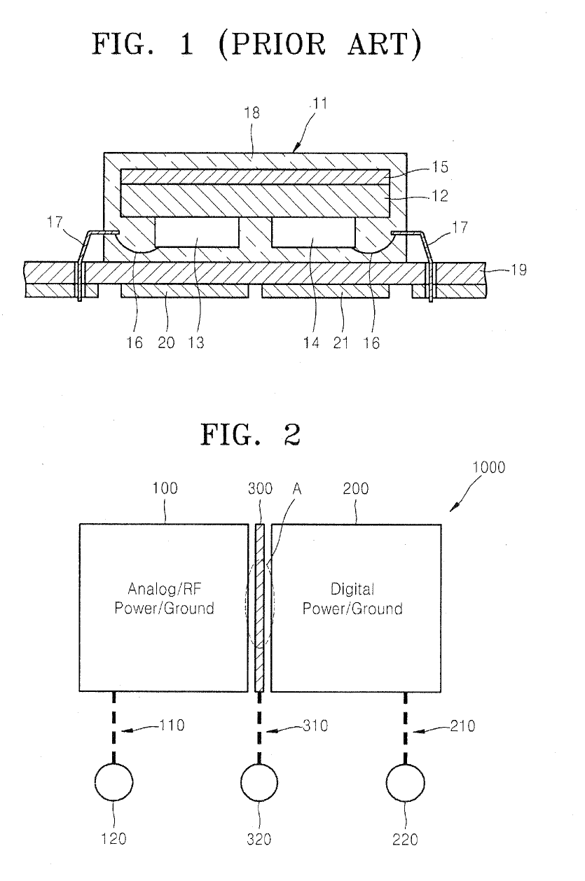

### DETAILED DESCRIPTION

The invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. In the drawings, the thicknesses of layers and regions are exaggerated for clarity. It will also be understood that when a layer is referred to as being “on” another layer or substrate, it can be directly on the other layer or substrate, or intervening layers may also be present. Like reference numerals in the drawings denote like elements, and thus their description will be omitted.

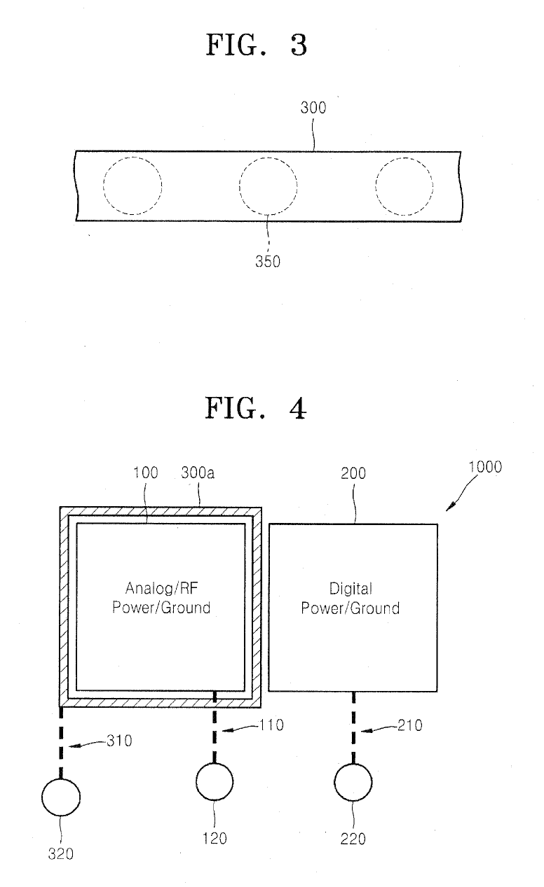

FIG. 2 is a plan view of a semiconductor package in which a ground shielding is formed between analog and digital circuit blocks, according to an embodiment of the invention. Here, only analog and digital circuit blocks on a circuit board are schematically shown, but the invention is not limited to analog and digital circuit blocks.

Referring to FIG. 2, the semiconductor package according to the present embodiment includes at least one semiconductor chip (not shown) and a circuit board 1000 on which the semiconductor chip is mounted and a plurality of circuit blocks is formed. The circuit blocks are mixed together on the circuit board 1000. However, in the present embodiment, only analog and digital blocks 100 and 200 are shown. The circuit board 1000 including a mixture of the analog and digital circuit blocks 100 and 200 may be an analog/digital mixed signal chip package board, a system in package (SIP) board, a multi-stacked package (MSP) board, a wafer level package (WLP) board, a flip chip package board, a package level printed circuit board (PCB), or the like.

The analog and digital circuit blocks 100 and 200 are connected to respective grounds to prevent noise therebetween as in a conventional semiconductor package. In other words, the analog circuit block 100 is connected to the ground of the analog circuit block 100 through an internal wire line 110, such as a via or the like, and a bump 120. In this way, the bump 120 is connected to the ground of the analog circuit block 100. The digital circuit block 200 is also connected to a digital circuit ground through an internal wire line 210 and a bump 220. However, as described above in the prior art, even if grounds of the analog and digital circuit blocks 100 and 200 are formed, coupling of high frequency noise generated by the analog circuit block 100 to a power and the ground of the digital circuit block 200 is not avoided.

Thus, in the present embodiment, a ground shielding 300 is formed between the analog and digital circuit blocks 100 and 200 to prevent high frequency noise coupling between the analog and digital circuit blocks 100 and 200. The ground shielding 300 is connected to a new ground separate from the grounds of the analog and digital circuit blocks 100 and 200. Thus, the semiconductor package of the present embodiment has a multi-ground shielding structure including the grounds of the analog and digital circuit blocks 100 and 200 and the ground shielding 300.

The ground shielding 300 may be connected to the most stable ground, e.g., a ground of a system board on which a semiconductor package is mounted, or a chipset level ground, so as to more efficiently prevent the high frequency noise coupling. If a ground connected to the ground shielding 300 is unstable, the ground shielding 300 may be coupled to other circuit blocks. The ground shielding 300 is connected through a wire line 310 to a bump 320 connected to the ground of the system board. Thus, the high frequency noise generated by the analog circuit block 100 is bypassed to the ground of the system board through the ground shielding 300 to prevent the high frequency noise from being transmitted to the digital circuit block 200.

The ground shielding 300 may be formed on the circuit board 1000 along with wire lines when the wire line is formed or may be formed separately from the wire lines. In this regard, it may be more convenient to form the ground shielding 300 along with the wire lines. The ground shielding 300 may have a meander line form. If the ground shielding 300 has a meander line form, a path through which the high frequency noise is bypassed to the ground of the system board may be lengthened. Thus, a power of the high frequency noise may be gradually decreased so as to more efficiently remove the high frequency noise.

A high frequency filter may be formed between the ground shielding 300 and the ground of a system board in order to selectively prevent and remove high frequency noise so as to more efficiently prevent noise. Here, the high frequency filter may be any filter such as an electro-static discharge (ESD) filter, a filter using a resistance-inductance-capacitance (RLC) circuit, or other filters capable of removing high frequency noise.

FIG. 3 is a detailed plan view of portion A of FIG. 2. Here, the ground shielding 300 may be connected to another ground shielding through vias 350. In other words, if a semiconductor package is formed in a stack structure, and thus a plurality of ground shieldings are respectively formed on a plurality of layers, the grounding shieldings may be connected to one another through the vias 350 formed on a plurality of layers and a circuit board. Thus, the ground shieldings may all be connected to a ground of the system board.

Although not shown, if a plurality of adjacent sections are formed between analog and digital blocks in a circuit board, ground shieldings for preventing noise may be each formed between an analog block and a digital block. The ground shieldings may be connected to one another through internal wire lines or vias to be connected to a ground of a common system board.

FIG. 4 is a plan view of a semiconductor package in which a ground shielding is formed between analog and digital circuit blocks, according to another embodiment of the invention. Once again, only analog and digital circuit blocks are schematically shown.

Referring to FIG. 4, in the semiconductor package according to the present embodiment, analog and digital circuit blocks 100 and 200 are adjacent to each other on a circuit board 1000. The analog and digital circuit blocks 100 and 200 are respectively connected to their grounds. A ground shielding 300a is formed between the analog and digital circuit blocks 100 and 200 and is slightly different from the ground shielding 300 of the previous embodiment.

In other words, the ground shielding 300a is formed between the analog and digital circuit blocks 100 and 200 and extends to enclose the analog circuit block 100. The ground shielding 300a is the same as the ground shielding 300 of the previous embodiment in that the ground shielding 300a is connected to a ground of a system board through an internal wire line 310 and a bump 320.

If the ground shielding 300a entirely encloses the analog circuit block 100 as in the present embodiment, the ground shielding 300a may prevent high frequency noise from the analog circuit block 100 from propagating in all directions. Thus, the high frequency noise may be prevented from being transmitted to the digital circuit block 200 and adjacent circuit blocks. Also, the high frequency noise may be prevented from permeating the digital circuit block 200 through another path.

In the present embodiment, the ground shielding 300a is formed to enclose the entire portion of the analog circuit block 100. However, the form of the ground shielding 300a is not limited to this. In other words, the ground shielding 300a may extend between the analog circuit blocks 100 and 200 to enclose only a portion of the analog circuit block 100. For example, a side of the ground shielding 300a may be open. The ground shielding 300a may be formed to have a form which partially encloses or entirely encloses the analog circuit block 100, and thus may take a variety of forms, depending on the form of the analog circuit block 100.

As described in the previous embodiment, in the present embodiment, the ground shielding 300a may be formed in a meander line form or a high frequency filter may be formed between grounds of a system board and the ground shielding 300a.

FIG. 5 is a plan view of a semiconductor package in which a ground shielding is formed between analog and digital circuit blocks, according to yet another embodiment of the invention. Here, only analog and digital circuit blocks are schematically shown.

Referring to FIG. 5, in the semiconductor package according to the present embodiment, unlike in the previous embodiments, a ground shielding 300b for preventing noise extends to enclose analog and digital circuit blocks 100 and 200. The ground shielding 300b having this form is connected to a ground of a system board through an internal wire line 310 and a bump 320.

The ground shielding 300b is formed to enclose the analog and digital circuit blocks 100 and 200 as described above so as to effectively prevent high frequency noise from being transmitted from the analog circuit block 100 to the digital circuit block 200. The ground shielding 300b can prevent the high frequency noise from being transmitted from the analog circuit block 100 to other circuit blocks and can also prevent other external noise from permeating the digital circuit block 200.

In the present embodiment, the ground shielding 300b is not limited to a form enclosing the analog and digital circuit blocks 100 and 200 but may be formed only partially enclosing the analog and digital circuit blocks 100 and 200. Alternatively, the ground shielding 300b may be formed in a meander line form. Also, a high frequency filter may be installed between the ground of the system board and the ground shielding 300b.

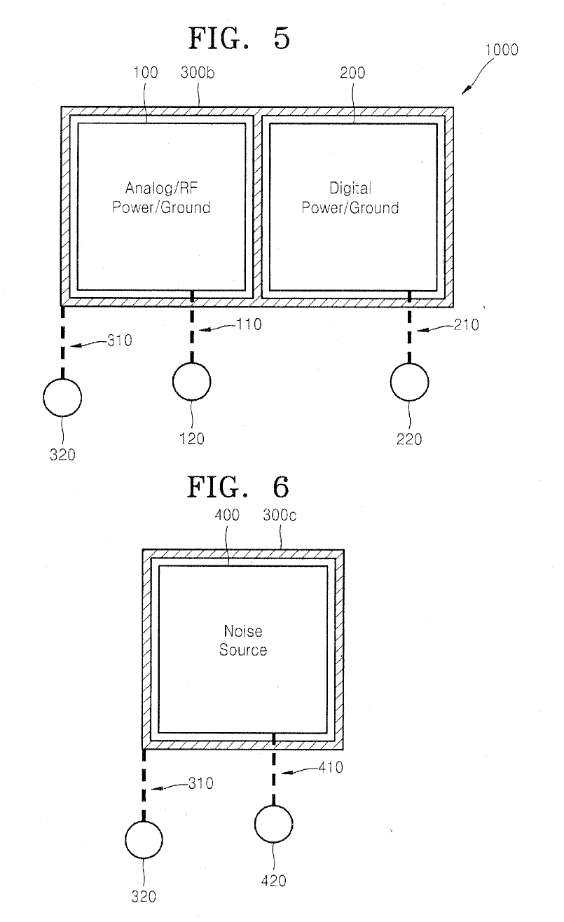

FIG. 6 is a plan view of a semiconductor package in which a ground shielding is formed around a noise source, according to another embodiment of the invention. Here, a ground shielding for preventing noise may be formed in all parts that behave as noise sources.

Referring to FIG. 6, in the semiconductor package according to the present embodiment, a ground shielding 300c is formed around a noise source 400 from which noise may be generated. The noise source 400 may be connected to a ground thereof through an internal wire line 410 and a bump 420 or may be connected to a ground of the analog circuit block 100. The ground shielding 300c is connected to a ground of a system board through an internal wire line 310 and a bump 320.

The noise source 400 will now be described with examples. A plurality of pins and a plurality of wire lines are formed in a semiconductor package to connect semiconductor chips to a circuit board. Pins and wire lines transmitting analog signals among the pins and wire lines formed in the semiconductor package may operate as high frequency noise sources. Thus, ground shielding may be formed to entirely or partially enclose such pins and wire lines to prevent high frequency noise. Here, the pins and wire lines may have single inline structures or differential line structures.

Analog and digital circuit blocks may be formed in each semiconductor chip of a semiconductor package. In the case of the semiconductor package, an entire analog chip may operate as a noise source. Thus, a ground shielding may be formed to entirely or partially enclose the analog chip to prevent high frequency noise coupling to other components in the semiconductor package.

The ground shielding is not limited to the above-described example but may be formed to enclose any part which can operate as a noise source. Also, such a ground shielding formed around a noise source may be formed in a meander line form, and a high frequency filter may be formed between the ground of the system board and the ground shielding.

As described in the embodiments, a ground shielding can be formed between circuit blocks to prevent a coupling problem caused by high frequency noise. The ground shielding bypasses a field resulting from excitation of an external source directly to the ground of the system board in terms of electro static discharge (ESD) or electromagnetic susceptibility (EMS). Thus, the ground shielding can reduce noise related to simultaneous switching noise (SSN), ESD, EMS, etc. and improve an overall electrical operation characteristic of the semiconductor package.

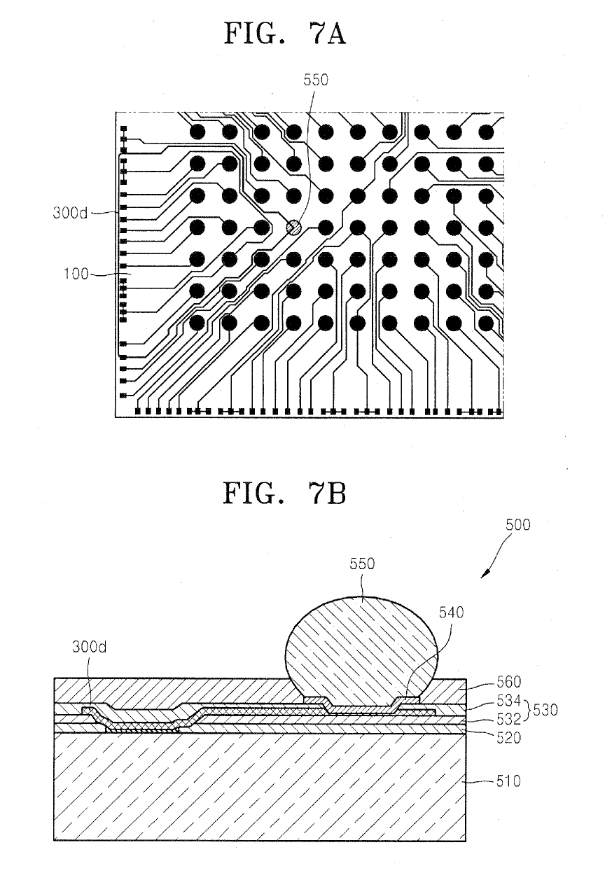

FIGS. 7A and 7B are a plan view and a cross-sectional view of a wafer level package (WLP) including a ground shielding according to another embodiment of the invention. Referring to FIG. 7A, in the WLP according to the present embodiment, a plurality of bumps, e.g., a plurality of solder balls, are formed and connected to one another through a plurality of wire lines. Here, an analog circuit block 100, which is a high frequency noise source, is enclosed by a ground shielding 300d. The ground shielding 300d is connected to a bump 550 connected to a ground of a system board. Thus, the ground shielding 300d for preventing noise can be adopted in the WLP to effectively prevent high frequency noise. As will be described with reference to FIG. 7B, in the case of the WLP, wire line layers formed on a semiconductor chip correspond to a circuit board of a semiconductor package, and the ground shielding 300d is formed on the wire line layers.

FIG. 7B is a cross-sectional view of the WLP. Here, only wire lines connected to a ground shielding 300 are shown.

Referring to FIG. 7B, a WIP 500 includes a silicon semiconductor chip 510, a passivation 520, a first insulator 530, the ground shielding 300d, and a bump 550. The passivation 520 is formed on the silicon semiconductor chip 510. The first insulator 530 insulates wire lines. The bump 550 connects the WLP 500 to a system board. The first insulator 530 may be formed of lower and upper layers 532 and 534. The ground shielding 300d is formed on the lower layer 532 and may be formed along with other wire lines when the other wire lines are formed. A second insulator 560 is formed on the first insulator 530 to protect the entire WLP 500, and the bump 550 is combined with an under bump metallergy (UBM) layer 540 formed on a portion of the ground shielding 300d.

In the WLP, layers on the silicon semiconductor chip 510, particularly, the first insulator 530, correspond to a circuit board of a semiconductor package, and the ground shielding 300d is formed on the first insulator 530, wherein wire lines are formed on the layers on the silicon semiconductor chip 510. The bump 550 connected to the ground shield 300d is connected to a ground of a system board on which the WLP 500 is mounted.

Multilayer wire lines may be formed in a WLP. In this case, a ground shielding may be formed in a multilayer structure, and ground shieldings between layers may be connected to one another through vias. Also, in the WLP, a ground shield having a meander line form may be formed, and a high frequency filter may be formed between a ground of a system board and the ground shielding 300d.

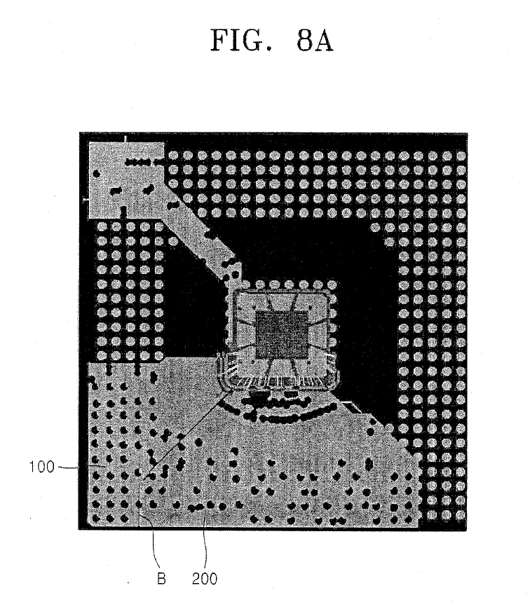

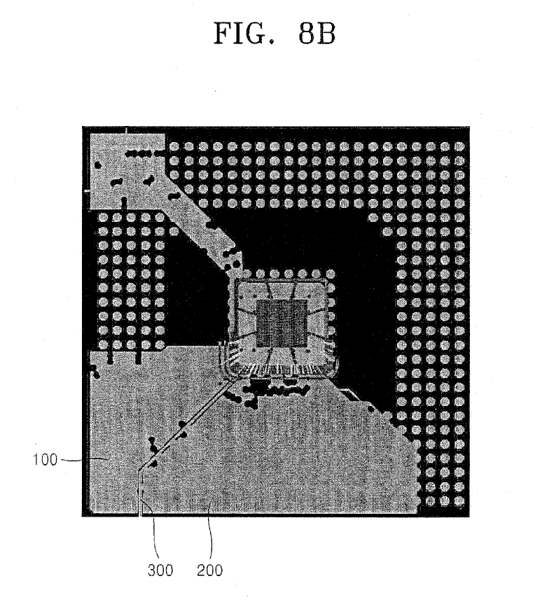

FIGS. 8A and 8B are views illustrating a conventional semiconductor package and a semiconductor package of the invention each including a ground shielding.

In the conventional semiconductor package shown in FIG. 8A, analog and digital circuit blocks 100 and 200 inside a circuit board are insulated from each other by an insulating line B. Grounds of the analog and digital circuit blocks 100 and 200 may be formed. Thus, a power and the ground of the analog circuit block 100 are coupled to a power and the ground of the digital circuit block 200 due to high frequency noise.

However, in the semiconductor package of the invention shown in FIG. 8B, the ground shielding 300 is formed between the analog and digital circuit blocks 100. High frequency noise is bypassed through the ground shielding 300. Thus, a coupling between powers and grounds of a circuit block and those of another circuit block caused by the high frequency noise can be effectively solved. In the present embodiment, ground shielding 300 is formed only between the analog and digital circuit blocks 100 and 200. However, the ground shielding 300 may extend to entirely or partially enclose the analog and digital circuit blocks 100 and 200.

A coupling capacitance between the analog and digital circuit blocks 100 and 200 was measured. According to the measurement result, the conventional semiconductor package shown in FIG. 8A has a capacitance of about 3.102 pF, while the semiconductor package of the invention has a capacitance of about 0.561 pF. In other words, coupling of the semiconductor package of the invention adopting a ground shielding was improved by about 80% compared to the conventional semiconductor package.

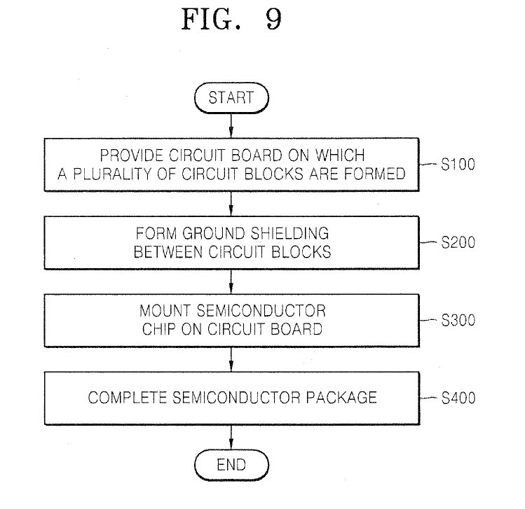

FIG. 9 is a flowchart of a method of fabricating a semiconductor package including a ground shielding, according to an embodiment of the invention. Referring to FIG. 9, in operation S100, a circuit board on which a plurality of circuit blocks is formed is provided. In operation S200, a ground shielding is formed between circuit blocks inside the circuit board, particularly, between analog and digital circuit blocks. The ground shielding is a ground which is separated from grounds of the plurality of circuit blocks and connected to a ground of a system board through a bump formed on the circuit board.

The ground shielding may be formed in a meander line form to increase a path of high frequency noise to reduce a power of the high frequency noise as described above. Also, a high frequency filter may be installed on the circuit board to be connected to the ground shielding. The high frequency filter may be installed on the circuit board or may be directly installed on a system board on which a semiconductor package is mounted. The high frequency filter may be formed separately from the ground shielding.

In the present embodiment, the ground shielding is formed on the circuit board on which circuit blocks have been formed. However, the ground shielding may be formed in a wiring process for forming the circuit blocks on the circuit board. In other words, the ground shielding may be formed during the wiring process to reduce production time and the number of processes.

In operation S300, a semiconductor chip is mounted on the circuit board. In operation S400, a bump and the like are formed on the circuit board to complete the semiconductor package. In the present embodiment, the ground shielding is formed between the analog and digital circuit blocks. However, the ground shielding may be formed around any portion behaving as a noise source. The ground shielding may be formed entirely or partially enclosing the noise source or may be formed entirely or partially enclosing a noise-sensitive area affected by noise.

If the semiconductor package is a WLP, a plurality of circuit blocks, i.e., wire lines, are formed on a silicon semiconductor chip. Next, ground shielding is formed between the circuit blocks. Here, the ground shielding may be formed during a wiring process for forming the circuit blocks to reduce production time and the number of processes.

As described above, in a multi-ground shielding semiconductor package, a method of fabricating the same package, and a method of preventing noise in the same package according to the invention, a new ground separate from the grounds of analog and digital circuit blocks, i.e., a ground shielding connected to a ground of a system board, can be formed between the analog and digital circuit blocks. Thus, high frequency noise generated by the analog circuit block can be bypassed through the ground shielding. As a result, a coupling problem between powers and grounds of the analog and digital circuit blocks can be effectively solved.

Also, the ground shielding is not limited to the formation between the analog and digital circuit blocks. That is, the ground shielding can be formed between noise sources, e.g., between pins or between wire lines. Thus, the high frequency noise can be more efficiently prevented. As a result, the overall electrical characteristics of the semiconductor package can be improved.

According to an aspect of the invention, there is provided a multi-ground shielding semiconductor package including: at least one semiconductor chip; and a circuit board on which the semiconductor chip is mounted and on which a plurality of circuit blocks are formed, wherein a conductive ground shielding is formed between the circuit blocks and separately from grounds of the circuit blocks to prevent noise between the circuit blocks.

The conductive ground shielding may be connected to a ground of a system board on which the circuit board is mounted or a chipset level ground. A high frequency filter may be connected between the conductive ground shielding and the ground of the system board. The system board is a printed circuit board (PCB) of a semiconductor device system. The conductive ground shielding may be formed in a meander line form.

The circuit board may be a circuit board on which analog and digital circuit blocks are mixed. The circuit board may be an analog/digital mixed signal chip package board, a system in package (SIP) board, a multi-stacked package (MSP) board, a wafer level package (WLP) board, a flip chip package board, or a package level PCB.

The conductive ground shielding may be formed between a noise source circuit block which generates noise and a noise-sensitive circuit block which is affected by the noise.

The conductive ground shielding extends to entirely or partially enclose the noise source circuit block or entirely or partially enclose the noise source circuit block and the noise-sensitive circuit block. The noise source circuit block may be an analog circuit block, and the noise-sensitive circuit block may be a digital circuit block.

If the circuit blocks are formed on each of semiconductor chips, the conductive ground shielding may be formed between the semiconductor chips. The conductive ground shielding may be formed between a noise source pin and a noise-sensitive pin or between a noise source wire line and a noise-sensitive wire line, which have one of a single inline form and a differential line form. The noise source pin or the noise source wire line may be a source pin or a source wire line connected to an analog circuit block, and the noise-sensitive pin or the noise-sensitive wire line may be a source pin or a wire line connected to a digital circuit block.

The semiconductor package may be formed in a structure in which a semiconductor chip or the circuit board is stacked to stack the circuit blocks, the conductive ground shielding may be stacked between the circuit blocks, and layers around which the ground shielding is formed may be connected to each other through vias. The semiconductor package may be a WLP, and a wire layer formed on a semiconductor chip of the WLP may correspond to the circuit board.

According to another aspect of the invention, there is provided a method of fabricating a multi-ground shielding semiconductor package, including: providing a circuit board on which a plurality of circuit blocks are formed; forming a conductive ground shielding between the circuit blocks and separately from grounds of the circuit blocks to prevent noise; and mounting at least one semiconductor chip on the circuit board.

According to another aspect of the invention, there is provided a method of fabricating a multi-ground shielding semiconductor package, including: forming a plurality of circuit blocks on a wafer on which a semiconductor chip is formed; and forming a conductive ground shielding between the circuit blocks and separately from grounds of the circuit blocks, wherein the conductive ground shielding prevents noise between the circuit blocks.

The conductive ground shielding may be connected to a ground of a system board on which the circuit board is mounted or a chipset level ground. The formation of the conductive ground shielding between the circuit blocks and separately from the grounds of the circuit blocks to prevent the noise may include forming a high frequency filter between the conductive ground shielding and the ground of the system board. If the conductive ground shielding is formed in a stack structure, the formation of the circuit blocks may include forming vias through which ground shieldings are connected to each other. The conductive ground shielding may be formed during a process of forming wires of the circuit board or may be separately formed.

The conductive ground shielding may be connected to a ground of a system board on which a circuit board is mounted or a chipset level ground.

According to another aspect of the invention, there is provided a method of preventing noise in a semiconductor package including a plurality of circuit blocks on a circuit board using a multi-ground shielding, including: forming a ground shielding between the circuit blocks and separately from grounds of the circuit blocks to prevent noise between the circuit blocks.

The ground shielding may be connected to a ground of a system board on which the circuit board is mounted or a chipset level ground. A high frequency filter may be formed between the ground shielding and the ground of the system board to prevent high frequency noise generated by an analog circuit block.

The ground shielding may be formed between a noise source circuit block which generates noise and a noise-sensitive circuit block which is affected by the noise. The noise source circuit block may be an analog circuit block, the noise-sensitive circuit block may be a digital circuit block, and the ground shielding may extend to entirely or partially enclose the analog circuit block or entirely or partially enclose the analog and digital circuit blocks.

While the invention has been particularly shown and described with reference to exemplary embodiments thereof, it will be understood by those of ordinary skill in the art that various changes in form and details may be made therein without departing from the spirit and scope of the invention as defined by the following claims.

What is claimed is:

1. A multi-ground shielding semiconductor package comprising:
at least one semiconductor chip;
a circuit board on which the semiconductor chip is mounted, the circuit board including a plurality of circuit blocks; and
a conductive ground shielding disposed between the circuit blocks and separately from grounds of the circuit blocks.

2. The multi-ground shielding semiconductor package of claim 1, wherein the conductive ground shielding is connected to one of a ground of a system board on which the circuit board is mounted and a chipset level ground.

3. The multi-ground shielding semiconductor package of claim 2, further comprising a high frequency filter connected between the conductive ground shielding and the ground of the system board or the chipset level ground.

4. The multi-ground shielding semiconductor package of claim 2, wherein the conductive ground shielding is connected to the ground of the system board or the chipset level ground through vias and a conductive bump disposed on the circuit board.

5. The multi-ground shielding semiconductor package of claim 2, wherein the system board is a PCB (printed circuit board) of a semiconductor device system.

6. The multi-ground shielding semiconductor package of claim 1, wherein the conductive ground shielding has a meander line form.

7. The multi-ground shielding semiconductor package of claim 1, wherein the circuit board is a circuit board on which analog and digital circuit blocks are mixed.

8. The multi-ground shielding semiconductor package of claim 7, wherein the circuit board is one of an analog/digital mixed signal chip package board, an SIP (system in package) board, an MSP (multi-stacked package) board, a WLP (wafer level package) board, a flip chip package board, and a package level PCB (printed circuit board).

9. The multi-ground shielding semiconductor package of claim 1, wherein the conductive ground shielding is disposed between a noise source circuit block which generates noise and a noise-sensitive circuit block which is affected by the noise.

10. The multi-ground shielding semiconductor package of claim 9, wherein the conductive ground shielding entirely or partially encloses the noise source circuit block or entirely or partially encloses the noise source circuit block and the noise-sensitive circuit block.

11. The multi-ground shielding semiconductor package of claim 9, wherein the noise source circuit block is an analog circuit block, the noise-sensitive circuit block is a digital circuit block, and the ground shielding entirely or partially encloses the analog circuit block or entirely or partially encloses the analog and digital circuit blocks.

12. The multi-ground shielding semiconductor package of claim 2, wherein the circuit blocks are each disposed on their own semiconductor chip, and the conductive ground shielding is disposed between the semiconductor chips.

13. The multi-ground shielding semiconductor package of claim 12, wherein the semiconductor chips comprise analog and digital chips, the conductive ground shielding is disposed between the analog and digital chips, and the conductive ground shielding encloses one of the analog chip and the analog and digital chips.

14. The multi-ground shielding semiconductor package of claim 1, wherein the conductive ground shielding is disposed between a noise source pin and a noise-sensitive pin or between a noise source wire line and a noise-sensitive wire line, which have one of a single inline form and a differential line form.

15. The multi-ground shielding semiconductor package of claim 14, wherein the conductive ground shielding extends to enclose the noise source pin or to entirely or partially enclose the noise source pin and the noise-sensitive pin.

16. The multi-ground shielding semiconductor package of claim 14, wherein the noise source pin or the noise source wire line is a source pin or a source wire line connected to an analog circuit block, and the noise-sensitive pin or the noise-sensitive wire line is a source pin or a wire line connected to a digital circuit block.

17. The multi-ground shielding semiconductor package of claim 1, wherein the semiconductor package is formed in a structure in which the circuit blocks are stacked, the conductive ground shielding is stacked between the circuit blocks, and layers around which the ground shielding is disposed are connected to each other through vias.

18. The multi-ground shielding semiconductor package of claim 1, wherein the semiconductor package is a WLP (wafer level package), and a wire layer disposed on a semiconductor chip of the WLP corresponds to the circuit board.

19. A method of fabricating a multi-ground shielding semiconductor package, comprising:
providing a circuit board, the circuit board including a plurality of circuit blocks;
forming a conductive ground shielding between the circuit blocks and separately from grounds of the circuit blocks; and
mounting at least one semiconductor chip on the circuit board.

20. The method of claim 19, wherein the conductive ground shielding is connected to one of a ground of a system board on which the circuit board is mounted and a chipset level ground.

21. The method of claim 20, further comprising forming a high frequency filter between the conductive ground shielding and the ground of the system board or the chipset level ground.

22. The method of claim 20, wherein forming the conductive ground shielding comprises forming a plurality of conductive ground shieldings on a respective plurality of layers, wherein the plurality of ground shieldings are connected to one another through vias.

23. The method of claim 19, wherein the conductive ground shielding is formed in a meander line form.

24. The method of claim 19, wherein the conductive ground shielding is formed between a noise source circuit block which generates noise and a noise-sensitive circuit block which is affected by the noise.

25. The method of claim 24, wherein the conductive ground shielding is formed to entirely or partially enclose the noise source circuit block or entirely or partially enclose the noise source circuit block and the noise-sensitive circuit block.

26. The method of claim 24, wherein the noise source circuit block is an analog circuit block, the noise-sensitive circuit block is a digital circuit block, and the conductive ground shielding is formed to entirely or partially enclose the analog circuit block or entirely or partially enclose the analog and digital circuit blocks.

27. The method of claim 19, wherein forming a conductive ground shielding comprises forming a conductive ground shielding and forming wires of the circuit board simultaneously.

28. A method of fabricating a multi-ground shielding semiconductor package, comprising:
forming a plurality of circuit blocks on a wafer on which a semiconductor chip is formed; and
forming a conductive ground shielding between the circuit blocks and separately from grounds of the circuit blocks, wherein the conductive ground shielding prevents noise between the circuit blocks.

29. The method of claim 28, wherein the conductive ground shielding is connected to one of a ground of a system board on which a circuit board is mounted and a chipset level ground.

30. The method of claim 28, wherein the conductive ground shielding is formed between a noise source circuit block which generates noise and a noise-sensitive circuit block which is affected by the noise.

31. The method of claim 28, wherein the conductive ground shielding is formed during a process of forming wires of the circuit blocks.

32. The method of claim 28, wherein forming a conductive ground shielding comprises forming the conductive ground shielding to entirely or partially enclose at least one of the circuit blocks.

33. A method of preventing noise in a semiconductor package comprising a plurality of circuit blocks on a circuit board using a multi-ground shielding, comprising:
forming a ground shielding between the circuit blocks and separately from grounds of the circuit blocks to prevent noise between the circuit blocks.

34. The method of claim 33, wherein the ground shielding is connected to one of a ground of a system board on which the circuit board is mounted and a chipset level ground.

35. The method of claim 33, further comprising forming a high frequency filter between the ground shielding and the ground of the system board or the chipset level ground.

36. The method of claim 33, wherein the ground shielding is formed in a meander line form.

37. The method of claim 33, wherein the ground shielding is formed between a noise source circuit block which generates noise and a noise-sensitive circuit block which is affected by the noise.

38. The method of claim 37, wherein the noise source circuit block is an analog circuit block, the noise-sensitive circuit block is a digital circuit block, and the ground shielding is formed to entirely or partially enclose the analog circuit block or entirely or partially enclose the analog and digital circuit blocks.

39. A device, comprising:
a circuit board;
a plurality of conductive structures on the circuit board, wherein the plurality of conductive structures are connected to at least one ground; and
a conductive ground shielding between the plurality of conductive structures, wherein the conductive ground shielding is connected to a ground different from the at least one ground.
